(19) United States
(12) Patent Application Publication
(10) Pub. No.: US 2022/0267639 A1
(43) Pub. Date: Aug. 25, 2022

(54) GATE INSULATING FILM FORMING COMPOSITION

(71) Applicant: Merck Patent GmbH, Darmstadt (DE)

(72) Inventors: Yukiharu URAOKA, Ikoma-shi (JP); Juan Paolo Soria BERMUNDO, Ikoma-shi (JP); Naofumi YOSHIDA, Yokohama-shi (JP); Megumi YANO, Kanagawa-shi (JP); Atsuko NOYA, Kanagawa-shi (JP); Toshiaki NONAKA, Tokyo (JP)

(21) Appl. No.: 17/621,713

(22) PCT Filed: Jun. 25, 2020
(86) PCT No.: PCT/EP2020/067769

§ 371 Date: Dec. 22, 2021

(30) Foreign Application Priority Data
Jun. 26, 2019 (JP) 2019-118623

(51) Int. Cl. C09D 183/06; C09D 7/61; H01L 29/786; H01L 29/40; H01L 29/49

(52) U.S. Cl. CPC C09D 183/06; C09D 7/61; H01L 29/78693; H01L 29/401; H01L 29/4908; H01L 29/66742

(57) ABSTRACT

[Problem] To provide a gate insulating film forming composition comprising a polysiloxane, which forms a gate insulating film having excellent characteristics such as high dielectric constant and high mobility. [Means for Solution] The gate insulating film forming composition comprises (I) a polysiloxane, (II) barium titanate, and (III) a solvent, wherein the content of the barium titanate is 30 to 80 mass % based on the total mass of the polysiloxane and the barium titanate.

### BACKGROUND OF THE INVENTION

### Technical Field

The present invention relates to a gate insulating film forming composition and a method for manufacturing a gate insulating film.

### Background Art

Recently, for high-resolution display, development of a thin film transistor using an oxide semiconductor represented by amorphous InGaZnO has been actively conducted. As compared with amorphous silicon thin film transistor used in liquid crystal displays, oxide semiconductor has large electron mobility and exhibits excellent electrical properties such as large ON/OFF ratio, so that it is expected as a driving element of organic EL displays and power saving elements. In the development for display, it has especially become an important issue to maintain the device operation stability as a transistor and uniformity on a large area substrate.

Conventionally, a gate insulating film of the thin film transistor has been formed by utilizing the chemical vapor deposition method (CVD) or the vacuum deposition equipment. In order to improve the characteristics of the insulating film and to simplify the manufacturing process, a method for forming an insulating film using various coating materials including organic and inorganic materials has been proposed. One of them is a method for forming an insulating film using a composition comprising a polysiloxane. For example, a method for forming an insulating film using a composition comprising a polysiloxane and a metal oxide has been proposed in order to control dielectric properties (Patent Document 1).

### PRIOR ART DOCUMENTS

### Patent Documents

[Patent document 1] JP 2014-199919 A

### SUMMARY OF THE INVENTION

### Problems to be Solved by the Invention

The present invention provides a gate insulating film forming composition comprising a polysiloxane, which forms a gate insulating film having excellent characteristics such as high dielectric constant and high mobility.

### Means for Solving the Problems

The gate insulating film forming composition according to the present invention comprises:

(I) a polysiloxane,

(II) barium titanate, and

(III) a solvent,

wherein the content of the barium titanate (II) is 30 to 80 mass % based on the total mass of the polysiloxane (I) and the barium titanate (II).

The method for manufacturing a gate insulating film according to the present invention comprises:

applying the composition according to the present invention onto a substrate to form a coating film, and

heating the formed coating film.

The thin film transistor according to the present invention comprises:

a gate electrode,

a gate insulating film manufactured by the above method,

an oxide semiconductor layer,

a source electrode, and

a drain electrode.

### Effects of the Invention

According to the gate insulating film forming composition of the present invention, a gate insulating film having excellent characteristics such as high dielectric constant, high mobility and low leakage current can be formed. Further, the formed gate insulating film has high flatness. Further, according to the present invention, a gate insulating film having excellent characteristics can be manufactured more easily.

### BRIEF DESCRIPTION OF THE DRAWINGS

FIG. 1 is a schematic drawing indicating one embodiment of a thin film transistor substrate comprising the gate insulating film according to the present invention.

FIG. 2 is a schematic drawing indicating another embodiment of a thin film transistor substrate comprising the gate insulating film according to the present invention.

FIG. 3 is a schematic drawing indicating another embodiment of a thin film transistor substrate comprising the gate insulating film according to the present invention.

FIG. 4 is a schematic drawing indicating another embodiment of a thin film transistor substrate comprising the gate insulating film according to the present invention.

### DETAILED DESCRIPTION OF THE INVENTION

### MODE FOR CARRYING OUT THE INVENTION

Embodiments of the present invention are described below in detail. In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the description such as “C_{x-y}”, “Cₓ-C_{y}” and “Cₓ” means the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when polymer has a plural types of repeating units, these repeating units copolymerize. These copolymerization are any of alternating copolymerization, random copolymerization, block copolymerization, graft copolymerization, or a mixture of any of these.

In the present specification, “%” represents mass % and “ratio” represents ratio by mass.

In the present specification, Celsius is used as the temperature unit. For example, 20 degrees means 20 degrees Celsius.

### <Gate Insulating Film Forming Composition>

The gate insulating film forming composition according to the present invention (hereinafter, sometimes simply referred to as the composition) comprises a polysiloxane (I), barium titanate (II), and a solvent (III). Here, the composition according to the present invention is a gate insulating film forming composition described later, and is preferably a composition for forming a gate insulating film constituting a thin film transistor.

The composition according to the present invention can be any of a non-photosensitive composition, a positive type photosensitive composition or a negative type photosensitive composition. In the present invention, the positive type photosensitive composition means a composition capable of forming a positive image, by the composition being applied to form a coating film, solubility of the exposed portion being increased in an alkali developing solution when exposed, and the exposed portion being removed by development. The negative type photosensitive composition means a composition capable of forming a negative image, by the composition being applied to form a coating film, the exposed portion being insolubilized in an alkali developing solution when exposed, and the unexposed portion being removed by development.

The relative dielectric constant of the gate insulating film formed by the composition according to the present invention is preferably 6.0 or more, and more preferably 8.0 or more. Here, the relative dielectric constant can be measured using the mercury probe equipment manufactured by Semilab.

### (I) Polysiloxane

Polysiloxane used in the present invention is not particularly limited and can be selected from any one according to the purpose. Depending on the number of oxygen atoms bonded to a silicon atom, the skeleton structure of polysiloxane can be classified as follows: a silicone skeleton (the number of oxygen atoms bonded to a silicon atom is 2), a silsesquioxane skeleton (the number of oxygen atoms bonded to a silicon atom is 3), and a silica skeleton (the number of oxygen atoms bonded to a silicon atom is 4). In the present invention, any of these can be used. Polysiloxane molecule can contain multiple combinations of these skeleton structures.

Preferably, polysiloxane to be used in the present invention comprises a repeating unit represented by the following formula (Ia):

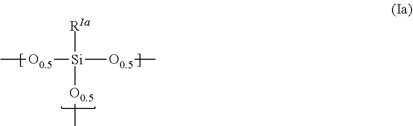

(wherein,
R^{Ia} represents hydrogen, a C₁₋₃₀ (preferably C₁₋₁₀), linear, branched or cyclic, saturated or unsaturated, aliphatic hydrocarbon group, or aromatic hydrocarbon group;
the aliphatic hydrocarbon group and the aromatic hydrocarbon group are each unsubstituted or substituted with fluorine, hydroxy or alkoxy, and
in the aliphatic hydrocarbon group and the aromatic hydrocarbon group, methylene is not replaced, or one or more methylene is replaced with oxy, imino or carbonyl, provided that R^{Ia} is not hydroxy or alkoxy).

Incidentally, here, the above-described methylene also includes a terminal methyl.

Further, the above-described “substituted with fluorine, hydroxy or alkoxy” means that a hydrogen atom directly bonded to a carbon atom in an aliphatic hydrocarbon group and aromatic hydrocarbon group is replaced with fluorine, hydroxy or alkoxy. In the present specification, the same applies to other similar descriptions.

In the repeating unit represented by the formula (Ia), R^{Ia} includes, for example, (i) alkyl, such as methyl, ethyl, propyl, butyl, pentyl, hexyl, heptyl, octyl and decyl, (ii) aryl, such as phenyl, tolyl and benzyl, (iii) fluoroalkyl, such as trifluoromethyl, 2,2,2-trifluoroethyl and 3,3,3-trifluoropropyl, (iv) fluoroaryl, (v) cycloalkyl, such as cyclohexyl, (vi) a nitrogen-containing group having an amino or imide structure, such as isocyanate and amino, and (vii) an oxygen-containing group having an epoxy structure, such as glycidyl, or an acryloyl structure or a methacryloyl structure. It is preferably methyl, ethyl, propyl, butyl, pentyl, hexyl and phenyl. The compound wherein R^{Ia} is methyl is preferred, since raw material thereof is easily obtained, its film hardness after curing is high and it has high chemical resistance. Further, the compound wherein R^{Ia} is phenyl is preferred, since it increases solubility of polysiloxane in the solvent and the cured film becomes hardly crackable.

Polysiloxane used in the present invention can further comprise a repeating unit represented by the following formula (Ib):

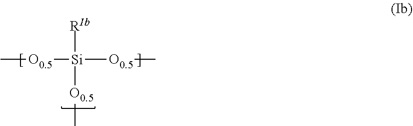

(wherein,
R^{Ib} is a group obtained by removing plural hydrogen from a nitrogen and/or oxygen-containing cycloaliphatic hydrocarbon compound having an amino group, an imino group and/or a carbonyl group).

In the formula (Ib), R^{Ib} is preferably a group obtained by removing plural hydrogen, preferably two or three hydrogen, from preferably a nitrogen-containing aliphatic hydrocarbon ring having an imino group and/or a carbonyl group, more preferably a 5-membered or 6-membered ring containing nitrogen as a member. For example, groups obtained by removing two or three hydrogen from piperidine, pyrrolidine or isocyanurate. R^{Ib} connects Si each other included in plural repeating units.

Polysiloxane used in the present invention can further comprise a repeating unit represented by the following formula (Ic):

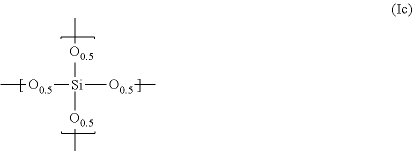

When the mixing ratio of the repeating units represented by the formulae (Ib) and (Ic) is high, photosensitivity of the composition decreases, compatibility with solvents and additives decreases, and the film stress increases, so that cracks sometimes easily generate. Therefore, it is preferably 40 mol % or less with, and more preferably 20 mol % or less, based on the total number of the repeating units of polysiloxane.

Polysiloxane used in the present invention can further comprise a repeating unit represented by the following formula (Id):

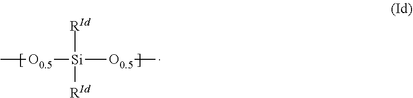

(wherein,
R^{Id} each independently represents hydrogen, a C₁₋₃₀ (preferably C₁₋₁₀, linear, branched or cyclic, saturated or unsaturated aliphatic hydrocarbon group or aromatic hydrocarbon group;
in the aliphatic hydrocarbon group and the aromatic hydrocarbon group, methylene is not replaced or replaced with oxy, imino or carbonyl, and the carbon atom is unsubstituted or substituted with fluorine, hydroxy or alkoxy).

In the repeating unit represented by the formula (Id), R^{Id} includes, for example, (i) alkyl, such as methyl, ethyl, propyl, butyl, pentyl, hexyl, heptyl, octyl and decyl, (ii) aryl, such as phenyl, tolyl and benzyl, (iii) fluoroalkyl, such as trifluoromethyl, 2,2,2-trifluoroethyl and 3,3,3-trifluoropropyl, (iv) fluoroaryl, (v) cycloalkyl, such as cyclohexyl, (vi) a nitrogen-containing group having an amino or imide structure, such as isocyanate and amino, and (vii) an oxygen-containing group having an epoxy structure, such as glycidyl, or an acryloyl structure or a methacryloyl structure. It is preferably methyl, ethyl, propyl, butyl, pentyl, hexyl and phenyl. The compound wherein R^{Id} is methyl is preferred, since raw material thereof is easily obtained, its film hardness after curing is high and it has high chemical resistance. Further, the compound wherein R^{Id} is phenyl is preferred, since it increases solubility of polysiloxane in the solvent and the cured film becomes hardly crackable.

By having the repeating unit of the above formula (Id), it is possible to make polysiloxane according to the present invention partially of a linear structure. However, since heat resistance is reduced, it is preferable that portions of linear structure are few. Specifically, the repeating unit of the formula (Id) is preferably 30 mol % or less and more preferably 5 mol % or less, based on the total number of the repeating units of polysiloxane. It is also one aspect of the present invention to have no repeating unit of the formula (Id) (0 mol %).

Further, polysiloxane used in the present invention can further comprises a repeating unit represented by the following formula (Ie):

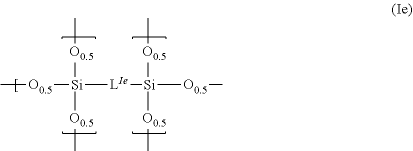

(wherein,
L^{Ie} is —(CR^{Ie}₂)ₙ— or

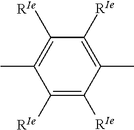

where, n is an integer of 1 to 3, and
R^{Ie} each independently represents hydrogen, methyl or ethyl).

In the formula (Ie), L^{Ie} is preferably —(CR^{Ie}₂)ₙ—, and R^{Ie} is identical or different in one repeating unit or in polysiloxane molecule. All R^{Ie} in one molecule are preferably identical, and it is preferred that all are hydrogen.

Polysiloxane used in the present invention can contain two or more types of repeating units. For example, it can contain three types of repeating units having repeating units represented by the formula (Ia) in which R^{Ia} is methyl or phenyl and a repeating unit represented by the formula (Ic).

In addition, polysiloxane contained in the composition according to the present invention preferably has a silanol group. Here, the silanol group refers to one in which an OH group is directly bonded to the Si skeleton of polysiloxane and is one in which hydroxy is directly attached to a silicon atom in polysiloxane comprising repeating units such as the above formulae (Ia) to (Ie). That is, the silanol is composed by bonding —O_{0.5}H to —O_{0.5}— in the above formulae (Ia) to (Ie). The content of the silanol in polysiloxane varies depending on the conditions for synthesizing polysiloxane, for example, the mixing ratio of the monomers, the type of the reaction catalyst and the like. The content of this silanol can be evaluated by quantitative infrared absorption spectrum measurement. The absorption band assigned to silanol (SiOH) appears as an absorption band having a peak in the range of 900±100 cm⁻¹ in the infrared absorption spectrum. When the content of the silanol is high, the intensity of this absorption band increases.

In the present invention, in order to quantitatively evaluate the silanol content, the intensity of the absorption band assigned to Si—O is used as a reference. An absorption band having a peak in the range of 1100±100 cm⁻¹ is adopted as a peak assigned to Si—O. The silanol content can be relatively evaluated by the ratio S2/S1, which is a ratio of the integrated intensity S2 of the absorption band assigned to SiOH to the integrated intensity S1 of the absorption band assigned to Si—O. In order to increase the dispersion stability of barium titanate and enable pattern formation in the case of photosensitivity, the ratio S2/S1 is preferably large. From such a viewpoint, in the present invention, the ratio S2/S1 is preferably 0.005 to 0.16, and more preferably 0.02 to 0.12.

The integrated intensity of the absorption band is determined in consideration of noise in the infrared absorption spectrum. In a typical infrared absorption spectrum of polysiloxane, an absorption band assigned to Si—OH having a peak in the range of 900±100 cm⁻¹ and an absorption band assigned to a Si—O having a peak in the range of 1100±100 cm⁻¹ are confirmed. The integrated intensity of these absorption bands can be measured as an area in consideration of a baseline in which noise and the like are considered. Incidentally, there is a possibility that the foot of the absorption band assigned to Si—OH and the foot of the absorption band assigned to Si—O are overlapped; however, in such a case, the wavenumber corresponding to the minimal point between the two absorption bands in the spectrum is set as their boundary. The same applies to the case where the foot of the other absorption band overlaps with the foot of the absorption band assigned to Si—OH or Si—O.

The composition according to the present invention can contain two or more types of polysiloxane. It is also possible to use, for example, polysiloxane containing the repeating units of the above formulae (Ia) to (Id) as the first type one and polysiloxane containing a repeating unit of the formula (Ie) and a repeating unit other than the formula (Ie) as the second type one.

It is preferable that R^{Ia} to R^{Id} in the repeating units (Ia) to (Id) are C₁₋₁₀ because the dispersion stability of barium titanate can be increased.

The mass average molecular weight of polysiloxane used in the present invention is not particularly limited. However, the higher the molecular weight, the more the coating properties tend to be improved. On the other hand, when the molecular weight is low, the synthesis conditions are less limited so that the synthesis is easy, and the synthesis of polysiloxane having a very high molecular weight is difficult. For these reasons, the mass average molecular weight of polysiloxane is usually 500 or more and 25,000 or less, and preferably 1,000 or more and 20,000 or less from the viewpoint of solubility in an organic solvent and solubility in an alkali developing solution in the case of photosensitivity. Here, the mass average molecular weight means a mass average molecular weight in terms of polystyrene, which can be measured by the gel permeation chromatography based on polystyrene.

Further, when polysiloxane used in the present invention is contained in a composition having photosensitivity, the composition is applied onto a substrate and through imagewise exposure and development, a cured film is formed. At this time, it is necessary that a difference in solubility occurs between the exposed area and the unexposed area, and the coating film in the exposed area should have above certain solubility to a developer. For example, it is considered that a pattern can be formed by exposure-development if dissolution rate of a pre-baked coating film to a 2.38% tetramethylammonium hydroxide (hereinafter sometimes referred to as TMAH) aqueous solution (hereinafter sometimes referred to as alkali dissolution rate or ADR, which is described later in detail) is 50 Å/sec or more. However, since the required solubility varies depending on the film thickness of the cured film to be formed and the development conditions, polysiloxane according to the development conditions should be appropriately selected. For example, if the film thickness is 0.1 to 100 μm (1,000 to 1,000,000 Å), in the case of positive type composition, the dissolution rate to a 2.38% TMAH aqueous solution is preferably 50 to 5,000 Å/sec, and more preferably 200 to 3,000 Å/sec. In the case of negative type composition, the dissolution rate to a 2.38% TMAH aqueous solution is preferably 50 to 20,000 Å/sec, and more preferably 1,000 to 10,000 Å/sec.

For polysiloxane used in the present invention, polysiloxane having any ADR within the above range can be selected depending on the application and required characteristics. By combining some polysiloxane having different ADR, a mixture having a desired ADR can be prepared.

Polysiloxane having different alkali dissolution rates and mass average molecular weights can be prepared by changing the catalyst, reaction temperature, reaction time or polymer. Using a combination of polysiloxane having different alkali dissolution rates, it is possible to improve reduction of residual insoluble matter after development, reduction of pattern reflow, pattern stability, and the like.

Such polysiloxane includes, for example,

(M) polysiloxane whose film after pre-baked is soluble to a 2.38 mass % TMAH aqueous solution and has dissolution rate of 200 to 3,000 Å/sec.

Further, a composition having a desired dissolution rate can be obtained, if necessary, by mixing with:

(L) polysiloxane whose film after pre-baked is soluble to a 5 mass % TMAH aqueous solution and has dissolution rate of 1,000 Å/sec or less, or

(H) polysiloxane whose film after pre-baked has dissolution rate to a 2.38 mass % TMAH aqueous solution of 4,000 Å/sec or more.

### [Measurement of Alkaline Dissolution Rate (ADR) and Calculation Method Thereof]

Using a TMAH aqueous solution as an alkaline solution, the alkali dissolution rate of polysiloxane or a mixture thereof is measured and calculated as described below.

Polysiloxane is diluted with PGMEA so as to be 35 mass % and dissolved while stirring at room temperature with a stirrer for 1 hour. In a clean room under an atmosphere of temperature of 23.0±0.5° C. and humidity of 50±5.0%, using a pipette, 1 cc of the prepared polysiloxane solution is dropped on the center area of a 4-inch silicon wafer having thickness of 525 μm and spin-coated to make the thickness 2±0.1 μm, and then the resultant film is heated on a hot plate at 100° C. for 90 seconds to remove the solvent. The film thickness of the coating film is measured with a spectroscopic ellipsometer (manufactured by J. A. Woollam).

Next, the silicon wafer having this film is gently immersed in a glass petri dish having a diameter of 6 inches, into which 100 ml of a TMAH aqueous solution adjusted to 23.0±0.1° C. and having a predetermined concentration was put, then allowed to stand, and the time until the coating film disappears is measured. The dissolution rate is determined by dividing by the time until the film in the area of 10 mm inside from the wafer edge disappears. In the case that the dissolution rate is remarkably slow, the wafer is immersed in a TMAH aqueous solution for a certain period and then heated for 5 minutes on a hot plate at 200° C. to remove moisture taken in the film during the dissolution rate measurement. Thereafter, film thickness is measured, and the dissolution rate is calculated by dividing the amount of change in film thickness before and after the immersion, by the immersion time. The above measurement method is performed 5 times, and the average of the obtained values is taken as the dissolution rate of polysiloxane.

### <Method for Synthesizing Polysiloxane>

Although the method for synthesizing polysiloxane used in the present invention is not particularly limited, it can be obtained by hydrolysis and polymerization of a silane monomer, for example, one represented by the following formula in the presence of an acidic catalyst or a basic catalyst as needed:

R^{ia}—Si—(OR^{ia′})₃ (ia)

(wherein,
R^{ia} is hydrogen, a C₁₋₃₀ (preferably C₁₋₁₀), linear, branched or cyclic, saturated or unsaturated aliphatic hydrocarbon group, or an aromatic hydrocarbon group,
in the aliphatic hydrocarbon group and the aromatic hydrocarbon group, methylene is not replaced or replaced with oxy, imino or carbonyl, and the carbon atom is unsubstituted or substituted with fluorine, hydroxy or alkoxy, and
R^{ia′} is linear or branched, C₁₋₆ alkyl).

In the formula (ia), preferred R^{ia′} includes methyl, ethyl, n-propyl, isopropyl, n-butyl and the like. In the formula (ia), a plurality of R^{ia′} are contained, and each R^{ia′} can be identical or different.

The preferred R^{ia′} is the same as the preferred R^{Ia} described above.

Specific examples of the silane monomer represented by the formula (ia) include, for example, methyltrimethoxysilane, methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, phenyltrimethoxysilane, phenyltriethoxysilane, trifluoromethyltrimethoxysilane, trifluoromethyltriethoxysilane, and 3,3,3-trifluoropropyltrimethoxysilane. Among these, methyltrimethoxysilane, methyltriethoxysilane, methyltripropoxysilane, and phenyltrimethoxysilane are preferable. It is preferable that two or more types of silane monomers represented by the formula (ia) are combined.

Further, a silane monomer represented by the following formula (ic) can be combined. When the silane monomer represented by the formula (ic) is used, polysiloxane comprising the repeating unit (Ic) can be obtained.

Si(OR^{ic′})₄ (ic)

wherein, R^{ic′} is linear or branched, C₁₋₆ alkyl.

In the formula (ic), preferred R^{ic′} includes methyl, ethyl, n-propyl, isopropyl, n-butyl and the like. In the formula (ic), a plurality of R^{ic′} are included, and each R^{ic′} can be identical or different.

Specific examples of the silane monomer represented by the formula (ic) include tetramethoxysilane, tetraethoxysilane, tetraisopropoxysilane, tetra n-butoxysilane and the like.

A silane monomer represented by the following formula (ib) can be further combined.

R^{ib}—Si—(OR^{ib′})₃ (ib)

wherein,
R^{ib′} is linear or branched, C₁₋₆ alkyl, and examples thereof include methyl, ethyl, n-propyl, isopropyl, n-butyl, and the like. A plurality of R^{ib′} are contained in one monomer, and each R^{ib′} can be identical or different.

R^{ib} is a group obtained by removing plural, preferably two or three, hydrogens from a nitrogen and/or oxygen-containing cyclic aliphatic hydrocarbon compound having an amino group, an imino group and/or a carbonyl group. The preferred R^{ib} is the same as the preferred R^{Ib} described above.

Specific examples of the silane monomer represented by the formula (ib) include tris-(3-trimethoxysilylpropyl)isocyanurate, tris-(3-triethoxysilylpropyl)isocyanurate, tris-(3-trimethoxysilylethyl)isocyanurate and the like.

Furthermore, a silane monomer represented by the following formula (id) can be combined. When the silane monomer represented by the formula (id) is used, polysiloxane containing the repeating unit (Id) can be obtained.

(R^{id})₂—Si—(OR^{id′})₂ (id)

wherein,
R^{id′} is each independently linear or branched, C₁₋₆ alkyl, and examples thereof include methyl, ethyl, n-propyl, isopropyl, n-butyl, and the like. A plurality of R^{id′} are contained in one monomer, and each R^{id′} can be identical or different,
R^{id} each independently represents hydrogen, a C₁₋₃₀ (preferably C₁₋₁₀), linear, branched or cyclic, saturated or unsaturated aliphatic hydrocarbon group or an aromatic hydrocarbon group, and
in the aliphatic hydrocarbon group and aromatic hydrocarbon group, methylene is not replaced or replaced with oxy, amino, imino or carbonyl, and the carbon atom is unsubstituted or substituted with fluorine, hydroxy or alkoxy. The preferred R^{id} is the same as the preferred R^{Id} described above.

Furthermore, a silane monomer represented by the following formula (ie) can be combined.

(OR^{ie′})₃—Si-L^{ie}-Si—(OR^{ie′})₃ (ie)

wherein,
R^{ie′} is each independently linear or branched, C₁₋₆ alkyl, and examples thereof include methyl, ethyl, n-propyl, isopropyl, n-butyl, and the like.
L^{ie} is —(CR^{ie}₂)ₙ—, or

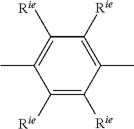

and preferably —(CR^{ie}₂)ₙ—. Here,
n is each independently an integer of 1 to 3, and
R^{ie} is each independently hydrogen, methyl or ethyl.

### (II) Barium Titanate

The composition according to the present invention comprises barium titanate (TiBaO₃) in an amount of 30 to 80 mass %, preferably 40 to 80 mass %, more preferably 50 to 70 mass %, based on the total mass of polysiloxane (I) and barium titanate (II). Barium titanate is not particularly limited as long as it has a high dielectric constant.

Due to the composition according to the present invention, which contains a specific amount of barium titanate, the dielectric constant of the formed gate insulating film can be increased and high mobility can be achieved. Further, reduction in leakage current and reduction in dielectric breakdown voltage can be achieved.

In addition, barium titanate has the feature of having good compatibility with polysiloxane (I), and can significantly improve the dispersion stability of the composition according to the present invention. Further, when polysiloxane has a silanol group, the dispersion stability can be further improved.

Usually, when the metal oxide particles are required to be uniformly dispersed in the composition, it is conducted that the metal oxide particles are made in advance in a dispersed state using a dispersant, then mixed with the solvent in the composition to improve the dispersion uniformity and dispersion stability. In the composition according to the present invention, barium titanate can be stably dispersed in the solvent in the composition without using any dispersant. For general metal oxide particles, polyoxyethylene alkyl phosphate, amidoamine salt of high molecular weight polycarboxylic acid, ethylenediamine PO-EO condensate, polyoxyethylene alkyl ether, polyoxyethylene alkyl phenol ether, alkyl glucosides, polyoxyethylene fatty acid ester, sucrose fatty acid ester, sorbitan fatty acid ester, polyoxyethylene sorbitan fatty acid ester and fatty acid alkanolamide are used as the dispersant, but there is a possibility that these dispersants remain in the insulating film and affect its electrical properties. Since the composition according to the present invention does not require any dispersant, better electrical properties can be achieved.

From such a viewpoint, the content of the dispersant in the composition according to the present invention is preferably 40 mass % or less, more preferably 20 mass % or less, further preferably 5 mass %, and still more preferably 1 mass %, based on the total mass of barium titanate. It is also one preferred aspect that the composition according to the present invention contains no dispersant (the content is 0%).

The particle shape of barium titanate is not limited, and can be spherical or amorphous. The average primary particle size of barium titanate measured by the dynamic scattering method is preferably 10 to 200 nm, more preferably 10 to 100 nm, and particularly preferably 20 to 50 nm.

### (III) Solvent

The solvent is not particularly limited as long as it uniformly dissolves or disperses the above-described polysiloxane and barium titanate as well as the additives that are optionally added. Examples of the solvent that can be used in the present invention include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates such as propylene glycol monomethyl ether acetate (PGMEA), propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate, methyl 3-methoxypropionate; and cyclic esters, such as γ-butyrolactone. Such a solvent can be used alone or in combination of two or more of any of these, and the amount thereof to be used varies depending on coating method or requirement of the film thickness after the coating.

In consideration of the coating method to be adopted, the content of the solvent in the composition according to the present invention can be appropriately selected according to the mass average molecular weight, its distribution and the structure of polysiloxane to be used. The composition according to the present invention comprises a solvent of generally 40 to 90 mass %, and preferably 60 to 80 mass %, based on the total mass of the composition.

The composition according to the present invention essentially comprises the above (I) to (III), but further compounds can be optionally combined. In addition, the content of the components other than (I) to (III) contained in the total composition is preferably 20 mass % or less, more preferably 15 mass % or less, and still more preferably 10 mass % or less, based on the total mass of the composition.

### (IV) Additive

The composition according to the present invention can be combined with further compounds other than (I) to (III). In one preferred aspect, the composition according to the present invention can further comprise an additive selected from the group consisting of a diazonaphthoquinone derivative, a silanol condensation catalyst, a silicon-containing compound and a fluorine-containing compound, in an amount of 0 to 20 mass % based on the total mass of the polysiloxane (I) and barium titanate (II). It is also one preferred aspect of the present invention that no additive is contained (the content of the additive is 0 mass %).

It is also a preferred embodiment of the present invention that the composition according to the present invention consists of the above-mentioned (I), (II), (III) and the above-mentioned additives, that is, contains no components other than these.

### [Diazonaphthoquinone Derivative]

When the composition according to the present invention is a positive type photosensitive composition, it preferably comprises a diazonaphthoquinone derivative. The diazonaphthoquinone derivative used in the present invention is a compound in which naphthoquinone diazide sulfonic acid is ester-bonded to a compound having a phenolic hydroxy group, and the structure is not particularly limited but is preferably an ester compound with a compound having one or more phenolic hydroxy groups. As the naphthoquinone diazide sulfonic acid, 4-naphthoquinone diazide sulfonic acid or 5-naphthoquinone diazide sulfonic acid can be used. Since the 4-naphthoquinonediazide sulfonic acid ester compound has absorption in i-line (wavelength: 365 nm) region, it is suitable for i-line exposure. Further, the 5-naphthoquinonediazide sulfonic acid ester compound has absorption in a broad range of wavelength and is therefore suitable for exposure in a broad range of wavelength. It is preferable to select an a 4-naphthoquinone diazide sulfonic acid ester compound or a 5-naphthoquinone diazide sulfonic acid ester compound according to the wavelength to be exposed. A mixture of a 4-naphthoquinone diazide sulfonic acid ester compound and a 5-naphthoquinone diazide sulfonic acid ester compound can also be used.

The compound having a phenolic hydroxy is not particularly limited, but examples thereof include bisphenol A, BisP-AF, BisOTBP-A, Bis26B-A, BisP-PR, BisP-LV, BisP-OP, BisP-NO, BisP-DE, BisP-AP, BisOTBP-AP, TrisP-HAP, BisP-DP, TrisP-PA, BisOTBP-Z, BisP-FL, TekP-4HBP, TekP-4HBPA, TrisP-TC (trade name, manufactured by Honshu Chemical Industry Co., Ltd.).

As far as the addition amount of the diazonaphthoquinone derivative is concerned, optimal amount thereof varies depending on the esterification ratio of naphthoquinone diazide sulfonic acid or the physical properties of polysiloxane used, and the required photosensitivity/dissolution contrast between the exposed area and the unexposed area, but is preferably 1 to 20 mass %, more preferably 2 to 15 mass %, and most preferably 3 to 10 mass %, based on the total mass of polysiloxane (I) and barium titanate (II). When the addition amount of the diazonaphthoquinone derivative is less than 1 mass %, the dissolution contrast between the exposed area and the unexposed area is too low, and there is no realistic photosensitivity. Further, in order to obtain more excellent dissolution contrast, 2 mass % or more is preferable. On the other hand, when the addition amount of the diazonaphthoquinone derivative is more than 20 mass %, whitening of the coating film occurs due to poor compatibility between polysiloxane and the quinonediazide compound, or colorless transparency of the cured film is sometimes lowered because coloring due to decomposition of the quinonediazide compound that occurs during thermal curing becomes remarkable. Further, since heat resistance of the diazonaphthoquinone derivative is inferior to that of polysiloxane, if the addition amount is increased, thermal decomposition causes deterioration of the electrical insulation of the cured film and outgassing, which sometimes becomes a problem in the subsequent processes. Furthermore, resistance of the cured film to a photoresist stripper containing monoethanolamine or the like as a main agent is sometimes lowered.

### [Silanol Condensation Catalyst]

In the case that the composition according to the present invention is a negative type photosensitive composition, it is preferable to comprise a silanol condensation catalyst selected from the group consisting of a photoacid generator, a photobase generator, a photothermal acid generator, and a photothermal base generator. Similarly, also in the case of imparting positive type photosensitivity, it is preferable to comprise any one or more silanol condensation catalysts, more preferably silanol condensation catalysts selected from a photoacid generator, a photobase generator, a photothermal acid generator, a photothermal base generator, a thermal acid generator, and a thermal base generator. It is preferable that these are selected according to the polymerization reaction and the crosslinking reaction used in the cured film production process.

As far as these contents are concerned, optimum amounts thereof vary depending on the type and amount of active substance generated by decomposition, the required photosensitivity/dissolution contrast between the exposed area and the unexposed area/pattern shape, but are preferably 0.1 to 10 mass %, and more preferably 0.5 to 5 mass %, based on the total mass of polysiloxane (I) and barium titanate (II). When the addition amount is less than 0.1 mass %, the amount of acid or base to be generated is too small and pattern reflow easily occurs. On the other hand, when the addition amount is more than 10 mass %, the cured film to be formed may be cracked, or prominently colored due to decomposition thereof, which sometimes invites reduction of the colorless transparency of the cured film. Further, when the addition amount is increased, this may cause deterioration of electrical insulation of the cured film and outgassing due to thermal decomposition, which sometimes becomes a problem in the subsequent processes. Furthermore, resistance of the cured film to a photoresist stripper containing monoethanolamine or the like as a main agent is sometimes lowered.

In the present invention, the photoacid generator or photobase generator refers to a compound that generates an acid or a base by causing bond cleavage upon exposure to light. The generated acid or base is considered to contribute to the polymerization of polysiloxane. Here, examples of the light include visible light, ultraviolet ray, infrared ray, X ray, electron beam, α ray, γ ray, or the like.

The photoacid generator or photobase generator to be added in the case of positive type preferably generates an acid or a base at the time of not an image-wise exposure for projecting a pattern (hereinafter referred to as the first exposure) but the flood exposure that is subsequently performed, and preferably has less absorption for the wavelength at the time of the first exposure. For example, when the first exposure is performed with g-line (peak wavelength: 436 nm) and/or h-line (peak wavelength: 405 nm) and the wavelength at the time of second exposure is performed with g+h+i line (peak wavelength: 365 nm), the photoacid generator or the photobase generator preferably has a larger absorbance at wavelength of 365 nm than that at 436 nm and/or 405 nm.

Specifically, the absorbance at wavelength of 365 nm/the absorbance at wavelength of 436 nm or the absorbance at wavelength of 365 nm/the absorbance at wavelength of 405 nm is preferably 2 or more, more preferably 5 or more, further preferably 10 or more, and most preferably 100 or more.

Here, the UV-visible absorption spectrum is measured using dichloromethane as a solvent. The measuring device is not particularly limited, but examples thereof include Cary 4000 UV-Vis spectrophotometer (manufactured by Agilent Technologies Japan, Ltd.).

The photoacid generator can be freely selected from generally used ones and examples thereof include diazomethane compounds, triazine compounds, sulfonic acid esters, diphenyliodonium salts, triphenylsulfonium salts, sulfonium salts, ammonium salts, phosphonium salts, sulfonimide compounds, and the like.

Specific examples of the photoacid generator that can be used, including those described above, are 4-methoxyphenyl diphenyl sulfonium hexafluorophosphonate, 4-methoxyphenyl diphenyl sulfonium hexafluoroarsenate, 4-methoxyphenyl diphenyl sulfonium methane sulfonate, 4-methoxyphenyldiphenylsulfonium trifluoroacetate, triphenylsulfonium tetrafluoroborate, triphenylsulfonium tetrakis(pentafluorophenyl)borate, triphenylsulfonium hexafluorophosphonate, triphenylsulfonium hexafluoroarsenate, 4-methoxyphenyl diphenyl sulfonium-p-toluene sulfonate, 4-phenyl thiophenyl diphenyl tetrafluoroborate, 4-phenyl thiophenyl diphenyl hexafluorophosphonate, triphenyl sulfonium methanesulfonate, triphenylsulfonium trifluoroacetate, triphenylsulfonium-p-toluenesulfonate, 4-methoxyphenyl diphenylsulfonium tetrafluoroborate, 4-phenylthiophenyl diphenyl hexafluoroarsenate, 4-phenylthiophenyl diphenyl-p-toluenesulfonate, N-(trifluoromethylsulfonyloxy)succinimide, N-(trifluoromethylsulfonyloxy)phthalimide, 5-norbornene-2,3-dicarboximidyl triflate, 5-norbornene-2,3-dicarboximidyl-p-toluenesulfonate, 4-phenylthiophenyldiphenyltrifluoromethanesulfonate, 4-phenylthiophenyl diphenyl trifluoroacetate, N-(trifluoromethylsulfonyloxy)diphenylmaleimide, N-(trifluoromethylsulfonyloxy)bicyclo[2.2.1]hept-5-ene-2,3-dicarboximide, N-(trifluoromethylsulfonyloxy)-naphthylimide, N-(nonafluorobutylsulfonyloxy)naphthylimide, and the like.

In addition, when absorption of h-line is not desired, use of 5-propylsulfonyloxyimino-5H-thiophen-2-ylidene-(2-methylphenyl)acetonitrile, 5-octylsulfonyl-oxyimino-5H-thiophene-2-ylidene-(2-methylphenyl)-acetonitrile, 5-camphorsulfonyloxyimino-5H-thiophene-2-ylidene-(2-methylphenyl)acetonitrile, 5-methylphenyl-sulfonyloxyimino-5H-thiophene-2-ylidene-(2-methylphenyl)acetonitrile should be avoided, since they have absorption in the wavelength region of h-line.

Examples of the photobase generator include multi-substituted amide compounds having an amide group, lactams, imide compounds or those containing the structure thereof.

Further, an ionic photobase generator containing an amide anion, a methide anion, a borate anion, a phosphate anion, a sulfonate anion, a carboxylate anion, and the like as an anion can also be used.

In the present invention, the photothermal acid generator or photothermal base generator refers to a compound that changes its chemical structure but does not generate any acid or base upon exposure to light, and then causes a bond cleavage by heat to generate an acid or base. Among these, the photothermal base generator is preferred. As the photothermal base generator, one represented by the general formula (II), more preferably hydrate or solvate thereof is mentioned. The compound represented by the formula (II) inverts to cis-form by exposure to light and becomes unstable, so that its decomposition temperature is decreased and a base is generated even if the baking temperature is about 100° C. in the subsequent process.

The photothermal base generator to be added in the case of positive type does not need to be adjusted with the absorption wavelength of the diazonaphthoquinone derivative.

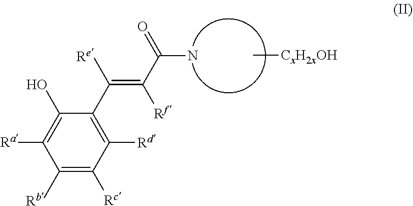

wherein,

x is an integer of 1 or more and 6 or less, and

R^{a′} to R^{f′} are each independently hydrogen, halogen, hydroxy, mercapto, sulfide, silyl, silanol, nitro, nitroso, sulfino, sulfo, sulfonato, phosphino, phosphinyl, phosphono, phosphonato, amino, ammonium, a C₁₋₂₀-aliphatic hydrocarbon group optionally having a substituent, a C₆₋₂₂-aromatic hydrocarbon group optionally having a substituent, a C₁₋₂₀-alkoxy optionally having a substituent, or a C₆₋₂₀-aryloxy optionally having a substituent.

Among these, for R^{a′} to R^{d′}, particularly hydrogen, hydroxy, a C₁₋₆ aliphatic hydrocarbon group, or C₁₋₆-alkoxy is preferable, and for R^{e′} and R^{f′}, particularly hydrogen is preferable. Two or more of R^{1′} to R^{4′} can be bonded to form a cyclic structure. At this time, the cyclic structure can contain a hetero atom.

N is a constituent atom of a nitrogen-containing heterocyclic ring, the nitrogen-containing heterocyclic ring is a 3- to 10-membered ring, and the nitrogen-containing heterocyclic ring can further have a C₁₋₂₀-, in particular C₁₋₆-, aliphatic hydrocarbon group, which can contain one or more substituents that are different from CₓH_{2X}OH shown in the formula (II).

It is preferred that R^{a′} to R^{d′} are appropriately selected according to the exposure wavelength to be used. In display applications, for example, unsaturated hydrocarbon bonding functional groups such as vinyl and alkynyl, which shift the absorption wavelength to g-, h- and i-line, and alkoxy, nitro or the like, are used, and particularly methoxy and ethoxy are preferred.

Specifically, the followings can be included.

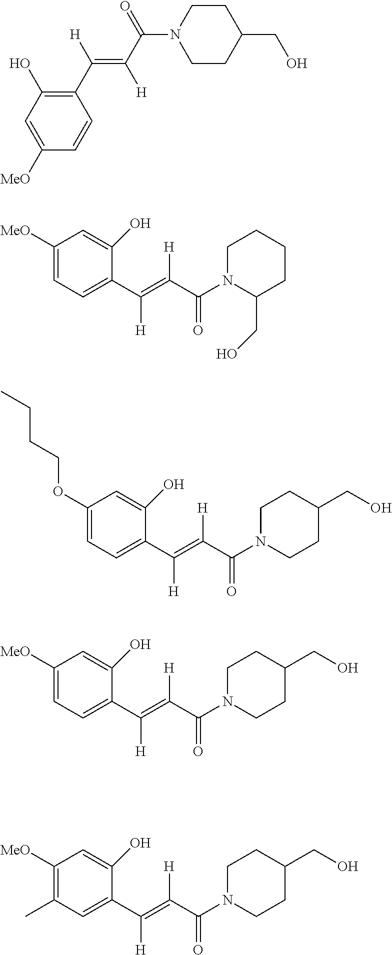 [SMILES: COc1ccc(/C=C/C(=O)N2CCC(CO)CC2)c(O)c1 ; COc1ccc(/C=C/C(=O)N2CCCCC2CO)c(O)c1 ; CCCCOc1ccc(/C=C/C(=O)N2CCC(CO)CC2)c(O)c1 ; COc1ccc(/C=C/C(=O)N2CCC(CO)CC2)c(O)c1 ; COc1cc(O)c(/C=C/C(=O)N2CCC(CO)CC2)cc1C]

In the present invention, the thermal acid generator or the thermal base generator refers to a compound that causes bond cleavage by heat to generate an acid or a base. It is preferable that these do not generate any acid or base by heat during pre-baking after application of the composition or generate only a small amount.

The thermal acid generators include salts and esters that generate organic acids, for example, various aliphatic sulfonic acids and salts thereof; various aliphatic carboxylic acids such as citric acid, acetic acid and maleic acid, and salts thereof; various aromatic carboxylic acids such as benzoic acid and phthalic acid, and salts thereof; aromatic sulfonic acids and ammonium salts thereof; various amine salts; aromatic diazonium salts; phosphonic acids and salts thereof; and the like. Among the thermal acid generators, in particular, a salt composed of an organic acid and an organic base is preferred, and a salt composed of sulfonic acid and an organic base is further preferred. Preferred sulfonic acids include p-toluenesulfonic acid, benzenesulfonic acid, p-dodecylbenzenesulfonic acid, 1,4-naphthalenedisulfonic acid, methanesulfonic acid, and the like. These acid generators can be used alone or in combination.

Examples of the thermal base generator include a compound that generates a base, such as imidazole, tertiary amine, and mixtures thereof. Examples of the base to be released include imidazole derivatives such as N-(2-nitrobenzyloxycarbonyl) imidazole, N-(3-nitrobenzyloxycarbonyl) imidazole, N-(4-nitrobenzyloxycarbonyl) imidazole, N-(5-methyl-2-nitrobenzyloxycarbonyl) imidazole and N-(4-chloro-2-nitrobenzyloxycarbonyl) imidazole, and 1,8-diazabicyclo[5.4.0]undecene-7. Like the acid generators, these base generators can be used alone or in combination.

### [Silicon-Containing Compound]

The composition of the present invention can comprise a silicon-containing compound other than those described above. Among the silicon-containing compounds, preferred are silicon-containing surfactants, which are used for the purpose of improving the coating properties of the composition. For example, organic siloxane surfactants are included, and it is possible to use KF-53 and KP341 (trade names, manufactured by Shin-Etsu Chemical Co., Ltd.). This silicon-containing compound is different from the above-mentioned polysiloxane being in a linear structure.

The addition amount of these silicon-containing compounds is preferably 0.005 to 1 mass %, and more preferably 0.01 to 0.5 mass %, based on the total mass of the composition.

### [Fluorine-Containing Compound]

The composition of the present invention can comprise a fluorine-containing compound. Among the fluorine-containing compounds, preferred are fluorine-containing surfactants. As the fluorine-containing surfactant, various ones are known, and all of them have a fluorinated hydrocarbon group and a hydrophilic group. Examples of such a fluorine-containing surfactant include Megaface (trade name: manufactured by DIC Corporation), Fluorad (trade name, manufactured by 3M Japan Limited), Surflon (trade name, manufactured by AGC Inc.), and the like.

The addition amount of these fluorine-containing compounds is preferably 0.005 to 1 mass %, and more preferably 0.01 to 0.5 mass %, based on the total mass of the composition.

The composition according to the present invention can comprise a surfactant other than those described above for the purpose of improving coating properties. Examples thereof include nonionic surfactants, anionic surfactants, amphoteric surfactants, and the like.

Examples of the above-described nonionic surfactant include polyoxyethylene polyoxypropylene block polymer; acetylene alcohol; acetylene glycol; acetylene alcohol derivatives, such as polyethoxylate of acetylene alcohol; acetylene glycol derivatives, such as polyethoxylate of acetylene glycol. Examples of the acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexanediol and the like.

Further, examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid and the like.

Further, examples of the amphoteric surfactant include 2-alkyl-N-carboxymethyl-N-hydroxyethyl imidazolium betaine, lauric acid amide propyl hydroxysulfone betaine and the like.

These surfactants can be used alone or as a mixture of two or more kinds, and the addition amount thereof is preferably 0.005 to 1 mass %, and more preferably 0.01 to 0.5 mass %, based on the total mass of the composition.

### <Method for Manufacturing Gate Insulating Film>

The method for manufacturing a gate insulating film according to the present invention comprises

applying the composition according to the present invention onto a substrate to form a coating film, and

heating the formed coating film.

In the case that the composition according to the present invention is a photosensitive composition, a patterned gate insulating film can be formed.

First, the composition according to the present invention is applied onto a substrate. Formation of the coating film of the composition in the present invention can be carried out by any method conventionally known as a method for coating a composition. Specifically, it can be freely selected from dip coating, roll coating, bar coating, brush coating, spray coating, doctor coating, flow coating, spin coating, slit coating and the like.

Further, as the substrate onto which the composition is applied, a suitable substrate such as a silicon substrate, a glass substrate, a resin film, or the like can be used. In the case that the substrate is a film, gravure coating can also be utilized. If desired, a drying process can be additionally provided after coating the film. Further, if necessary, the coating process can be repeated once or twice or more to make the film thickness of the coating film to be formed as desired.

After forming the coating film of the composition according to the present invention, it is preferable to carry out pre-baking (heat treatment) of the coating film in order to dry the coating film and reduce the residual amount of the solvent. The pre-baking process can be carried out at a temperature of generally 70 to 150° C., preferably 90 to 120° C., in the case of a hot plate, for 10 to 180 seconds, preferably 30 to 90 seconds and in the case of a clean oven, for 1 to 30 minutes.

In the case of a non-photosensitive composition, the coating film is then heated and cured. The heating temperature in this heating process is not particularly limited and can be freely determined as long as it is a temperature at which dehydration condensation of polysiloxane proceeds and curing of the coating film can be performed. However, if the silanol group remains, the chemical resistance of the cured film sometimes becomes insufficient, or the leakage current of the cured film is sometimes increased. From such a viewpoint, in general, a relatively high temperature is selected as the heating temperature. In order to accelerate the curing reaction and obtain a sufficient cured film, the heating temperature is preferably 250 to 800° C., and more preferably 300 to 500° C. Further, the heating time is not particularly limited and is generally 10 minutes to 24 hours, and preferably 30 minutes to 3 hours. In addition, this heating time is a time from when the temperature of the film reaches a desired heating temperature. Usually, it takes about several minutes to several hours for the pattern film to reach a desired temperature from the temperature before heating. The heating is performed in an inert gas atmosphere or in an oxygen-containing atmosphere such as the air.

An additional heating process can be performed after the above-mentioned heating (hereinafter, sometimes referred to as curing heating). The additional heating is preferably performed at a temperature equal to or higher than the annealing temperature of the device so that water is not generated due to a chemical change (polymerization) of polysiloxane and does not affect transistor performance. The additional heating can be performed by heating at a temperature equal to or higher than the curing heating temperature. The temperature of the additional heating is preferably 250 to 800° C., and more preferably 300 to 500° C. The additional heating time is generally 20 minutes to 2 hours, and preferably 40 minutes to 1 hour. The atmosphere, in which the additional heating treatment is performed, is an inert gas atmosphere or an oxygen-containing atmosphere as in the case of the curing heating. However, it is also possible to perform the additional heating in an atmosphere different from that in the thermal curing process.

In the case of a photosensitive composition, after applying, the coating film surface is irradiated with light. As a light source to be used for the light irradiation, any one conventionally used for a pattern forming method can be used. As such a light source, a high-pressure mercury lamp, a low-pressure mercury lamp, a lamp of metal halide, xenon or the like, a laser diode, an LED and the like can be included. Ultraviolet ray such as g-line, h-line and i-line is usually used as the irradiation light. Except ultrafine processing for semiconductors or the like, it is general to use light of 360 to 430 nm (high-pressure mercury lamp) for patterning of several μm to several dozens of μm. Above all, in the case of liquid crystal display devices, light of 430 nm is often used. The energy of the irradiation light is generally 5 to 2,000 mJ/cm², preferably 10 to 1,000 mJ/cm², although it depends on the light source and the film thickness of the coating film. If the irradiation light energy is lower than 5 mJ/cm², sufficient resolution cannot be obtained in some cases. On the other hand, when the irradiation light energy is higher than 2,000 mJ/cm², the exposure becomes excess and occurrence of halation is sometimes brought.

In order to irradiate light in a pattern shape, a general photomask can be used. Such a photomask can be freely selected from well-known ones. The environment at the time of irradiation is not particularly limited, but it may generally be set in an ambient atmosphere (in the air) or nitrogen atmosphere. Further, in the case of forming a film on the entire surface of the substrate, light irradiation can be performed over the entire surface of the substrate. In the present invention, the pattern film also includes such a case where a film is formed on the entire surface of the substrate.

After the exposure, to promote the reaction between polymer in the film by the acid or base generated in the exposed area, particularly in the case of the negative type, post exposure baking can be performed as necessary. Different from the heating process to be described later, this heat treatment is performed not to completely cure the coating film but to leave only a desired pattern on the substrate after development and to make other areas capable of being removed by development. When post exposure baking is performed after exposure, a hot plate, an oven, a furnace, and the like can be used. The heating temperature should not be excessively high because it is not desirable for the acid or base in the exposed area generated by light irradiation to diffuse to the unexposed area. From such a viewpoint, the range of the heating temperature after exposure is preferably 40° C. to 150° C., and more preferably 60° C. to 120° C. To control the curing rate of the composition, stepwise heating can be applied, as needed. Further, the atmosphere during the heating is not particularly limited and can be selected from in an inert gas such as nitrogen, under a vacuum, under a reduced pressure, in an oxygen gas and the like, for the purpose of controlling the curing rate of the composition. Further, the heating time is preferably above a certain level in order to maintain higher the uniformity of temperature history in the wafer surface and is preferably not excessively long in order to suppress diffusion of the generated acid or base. From such a viewpoint, the heating time is preferably 20 seconds to 500 seconds, and more preferably 40 seconds to 300 seconds. It is preferable not to perform the post exposure baking when a photoacid generator, a photobase generator, a thermal acid generator or a thermal base generator is added to a positive type photosensitive composition, in order not to generate acid or base thereof at this stage and not to promote the crosslinking between polymer.

After that, the coating film is developed. As the developer to be used at the time of development, any developer conventionally used for developing a photosensitive composition can be used. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), aqueous ammonia, alkylamine, alkanolamine and heterocyclic amine, and a particularly preferable alkali developer is a TMAH aqueous solution. In these alkali developers, a water-soluble organic solvent such as methanol and ethanol, or a surfactant can be further contained, if needed. The developing method can also be freely selected from conventionally known methods. Specifically, methods such as dipping in a developer (dip), paddle, shower, slit, cap coat, spray and the like can be included. After development with a developer, by which a pattern can be obtained, it is preferable that rinsing with water is carried out.

After that, a flood exposure process is usually performed. When a photoacid generator or a photobase generator is used, an acid or a base is generated in this flood exposure process. When a photothermal acid generator or a photothermal base generator is used, chemical structure changes in this flood exposure process. Further, when there is an unreacted diazonaphthoquinone derivative remaining in the film, it is photodegraded and the optical transparency of the film is further increased; therefore, it is preferable to perform the flood exposure process when transparency is required. When a thermal acid generator or a thermal base generator is selected, the flood exposure is not essential, but it is preferable to perform the flood exposure for the above purpose. As the method of flood exposure, there is a method for exposing light over the entire surface with about 100 to 2,000 mJ/cm² (in terms of exposure amount at wavelength of 365 nm) using an ultraviolet visible exposure machine such as an aligner (for example, PLA-501F, manufactured by Canon Inc.).

Curing of the coating film is performed by heating the obtained pattern film. The heating conditions are the same as the case in which the above-described non-photosensitive composition is used. Similarly, the additional heating can be performed.

The film thickness of the gate insulating film thus obtained is not particularly limited and is preferably 100 to 300 nm, and more preferably 100 to 200 nm.

### <Thin Film Transistor>

The thin film transistor according to the present invention comprises a gate electrode, a gate insulating film formed using the composition according to the present invention, an oxide semiconductor layer, a source electrode, and a drain electrode.

The gate electrode is a single layer or a laminated film of two or more types of materials such as molybdenum, aluminum and aluminum alloy, copper and copper alloy, and titanium. As the oxide semiconductor layer, an oxide semiconductor composed of indium oxide, zinc oxide, and gallium oxide is generally used, but any other oxides can be also used as long as they exhibit semiconductor characteristics. The method for forming the oxide semiconductor layer includes a sputtering method, which forms a film using a sputtering target having the same composition as the oxide semiconductor by means of DC sputtering or RF sputtering, or a liquid phase method, which forms the oxide semiconductor layer by applying and baking a precursor solution of metal alkoxide, metal organic acid salt or chloride, or a dispersion of the oxide semiconductor nanoparticle. The source and drain electrodes are, for example, a single layer or a laminated film of two or more types of materials such as molybdenum, aluminum and an aluminum alloy, copper and a copper alloy, and titanium.

In the present specification, the thin film transistor refers to all the device which constitutes a thin film transistor such as a substrate comprising an electrode, an electrical circuit, a semiconductor layer and an insulating layer on its surface. Further, the wiring arranged on the substrate includes a gate wiring, a data wiring, a via wiring for connecting two or more wiring layers, and the like

The thin film transistor according to the present invention can further comprise a protective film. It is also possible to form a protective film using the composition according to the present invention.

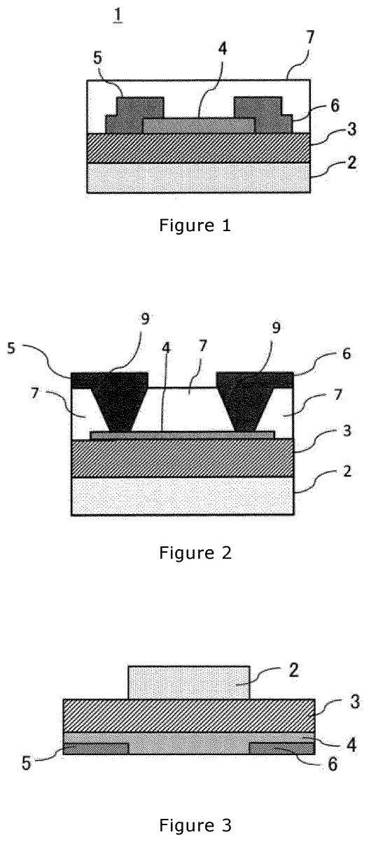

In FIG. 1, one aspect of a bottom gate type thin film transistor 1 comprising an insulating film formed using the composition according to the present invention is shown. In FIG. 1, a gate insulating film 3 is formed on a gate electrode 2, and an oxide semiconductor layer 4 is formed thereon. Additionally, a source electrode 5 and a drain electrode 6 are respectively formed at both ends of the semiconductor layer 4 so as to be in contact with the gate insulating film 3.

Although not shown in the figure, on the semiconductor layer 4, an etch stopper can be formed. Additionally, a protective film 7 can be formed so as to cover these semiconductor layer 4, source electrode 5 and drain electrode 6. As another aspect, the same can be applied to, for example, a thin film transistor substrate (FIG. 2) having a structure, in which a source electrode 5 in contact with the semiconductor layer 4, and a drain electrode 6 are formed through a contact hole 9 on a protective film 7, or a thin film transistor having a top gate structure (FIG. 3). In addition, the structures shown here are merely examples, and thin film transistor substrates having a structure other than the structures shown here can be manufactured by the manufacturing method according to the present invention.

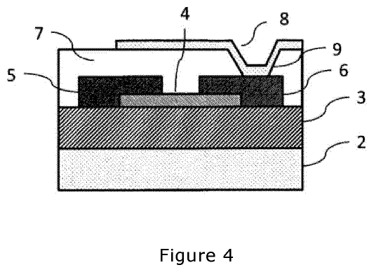

In FIG. 4, one aspect of a thin film transistor substrate in which a pixel electrode 8 is formed on a protective film 7 is shown. The pixel electrode 8 and the drain electrode 6 are in contact via a contact hole 9 formed in the protective film.

### EXAMPLES

The present invention is described in more detail with reference to the following examples.

### Synthesis Example

### Synthesis of Polysiloxane (P1)

Into a 2 L flask equipped with a stirrer, a thermometer and a condenser tube, 49.0 g of a 25 mass % TMAH aqueous solution, 600 ml of isopropyl alcohol (IPA) and 4.0 g of water were charged, and then a mixed solution of 68.0 g of methyltrimethoxysilane, 79.2 g of phenyltrimethoxysilane and 15.2 g of tetramethoxysilane was prepared in a dropping funnel. The mixed solution was added dropwise at 40° C., and the resulting product was stirred at the same temperature for 2 hours and then neutralized by adding a 10 mass % HCI aqueous solution. To the neutralized liquid, 400 ml of toluene and 600 ml of water were added to separate the resulting product into two phases, and the aqueous phase was removed. Furthermore, the resulting product was washed three times with 300 ml of water, the obtained organic phase was concentrated under reduced pressure to remove the solvent, PGMEA was added to the concentrate to prepare a solid content concentration of 35 mass %, thereby obtaining Polysiloxane P1 solution.

When the molecular weight (in terms of polystyrene) of the obtained Polysiloxane P1 was measured by the gel permeation chromatography, the mass average molecular weight (hereinafter sometimes abbreviated as “Mw”) was 1,700. Further, the obtained resin solution was applied onto a silicon wafer using a spin coater (MS-A100, manufactured by Mikasa Co., Ltd.) to make the film thickness after pre-baking become 2 μm, and when the dissolution rate (hereinafter sometimes abbreviated as “ADR”) to a 2.38 mass % TMAH aqueous solution was measured after pre-baking, it was 1,200 Å/sec.

Further, when the infrared absorption spectrum of the obtained Polysiloxane (P1) was measured, the ratio of the integrated intensity S1 of the absorption band assigned to Si—O and the integrated intensity S2 of the absorption band assigned to SiOH, S2/S1 was 0.08.

### Preparation of Composition A

Barium titanate BaTiO₃ (primary particle size: 20 nm) was gradually added to Polysiloxane P1 solution obtained above for about 10 minutes so that the mass ratio of polysiloxane:barium titanate becomes 30:70, and after stirring for about 15 minutes, the mixture was dispersed using an SC mill. Additionally, a thermal base generator (1,8-diazabicyclo(5.4.0)undecene-7-orthophthalate) was added to make its concentration become 500 ppm, the surfactant KF-53 (manufactured by Shin-Etsu Chemical Co., Ltd.) was added to make its concentration become 1,000 ppm, and further PGMEA was added to make its solid content concentration become 30 mass %, and the mixture was stirred, thereby obtaining Composition A.

### Preparation of Compositions B, C and D

Composition B was obtained in the same manner as Composition A, except that the mass ratio of polysiloxane:barium titanate was 37:63.

Composition C was obtained in the same manner as Composition B, except that the thermal base generator was not added.

Composition D was obtained in the same manner as Composition A, except that the mass ratio of polysiloxane:barium titanate was 51:49.

### Preparation of Positive Type Photosensitive Composition E

Instead of the thermal base generator in Composition D, as a diazonaphthoquinone derivative, 4,4′-(1-(4-(1-(4-hydroxyphenyl))-1-methylethyl) phenyl)-ethylidene) bisphenol modified with 2.0 mol of diazonaphthoquinone was added in an amount of 8 mass % based on the total mass of Polysiloxane P1 and barium titanate, and the mixture was stirred, thereby preparing Composition E.

### Preparation of Negative Type Photosensitive Composition F

Instead of the thermal base generator in Composition D, as a photoacid generator, 1,8-naphthalimidyl triflate was added in an amount of 2 mass % based on the total mass of Polysiloxane P1 and barium titanate, and the mixture was stirred, thereby preparing Composition F.

### Preparation of Comparative Compositions A and B

Comparative Composition A was obtained in the same manner as Composition A, except that barium titanate was not contained.

Comparative Composition B was obtained in the same manner as Composition A, except that titanium oxide TiO₂ (primary particle size: 20 nm) was used instead of barium titanate and the mass ratio of polysiloxane:titanium oxide was changed to 37:63.

### Comparative Compositions C and D

Comparative Composition C was obtained in the same manner as Composition A, except that the mass ratio of polysiloxane:barium titanate was changed to 86:14 and they were added.

Comparative Composition D was obtained in the same manner as Composition A, except that polysiloxane:barium titanate mass ratio was 93:7 and they were added.

### Example 101

The above Composition A was applied onto a n-doped silicon wafer by spin coating. The obtained coating film was prebaked at 110° C. for 90 seconds to evaporate the solvent. Then, the coating film was heated at 300° C. in the air for 20 minutes and cured, thereby forming a gate insulating film having the film thickness of 0.1 μm. A film of amorphous InGaZnO was formed on the gate insulating film by the RF sputtering method (70 nm). After forming a pattern of the amorphous InGaZnO film, the source and drain electrodes were patterned. Molybdenum was used as the source and drain electrodes material. Thereafter, annealing was performed in an N₂/O₂ (4:1) atmosphere at 300° C. for 120 minutes, thereby obtaining a thin film transistor of Example 101.

### Examples 102 to 106 and Comparative Examples 101 and 103 to 105

Thin film transistors of Examples 102 to 106 and Comparative Examples 101 and 103 to 105 were obtained in the same manner as in Example 101, except respectively that the compositions shown in Table 1 were used and the heating temperature was the temperature shown in Table 1, and that the film thickness after curing in Example 104 was 0.2 μm and the annealing temperature in Example 105 was 180° C. The thin film transistor of Comparative Example 102 was obtained in the same manner as in Example 101, except that a thermal oxide film having the film thickness of 0.1 μm was used as a gate insulating film.

### Example 107

The above Composition E was applied in the same manner as in Example 101, and the obtained coating film was prebaked at 100° C. for 90 seconds to evaporate the solvent. The coating film after dried was subjected to paddle development using a 2.38% TMAH aqueous solution for 90 seconds, further rinsed with pure water for 60 seconds, subjected to flood exposure at 1,000 mJ/cm², and thereafter heated and cured at 300° C. in the air for 60 minutes, thereby forming a gate insulating film having the film thickness of 0.1 μm. Thereafter, film formation, pattern formation and annealing were performed in the same manner as in Example 101, thereby obtaining a thin film transistor of Example 107.

### Example 108

The above Composition F was applied in the same manner as in Example 101, and the obtained coating film was pre-baked at 100° C. for 90 seconds to evaporate the solvent. The coating film after dried was exposed at 100 to 200 mJ/cm² using the g+h+i-line mask aligner (PLA-501F type, product name, manufactured by Canon Inc.). After exposure, the coating film was heated at 100° C. for 60 seconds, and then subjected to paddle development using a 2.38% TMAH aqueous solution for 60 seconds, and further rinsed with pure water for 60 seconds. The coating film was heated and cured at 300° C. in the air for 60 minutes, thereby forming a gate insulating film having the film thickness of 0.1 μm. Thereafter, film formation, pattern formation and annealing were performed in the same manner as in Example 101, thereby obtaining a thin film transistor of Example 108.

For Example 102, when the flatness of the gate insulating film was measured by scanning using AFM5300E, manufactured by Hitachi High-Tech Science Corporation, in a range of 1 μm square, the root-mean-square roughness was 2.95 nm.

The following characteristic values were measured for the obtained thin film transistors. The obtained results were as shown in Table 1.

TABLE 1

| | | | An- | | | Break | Carrier | |
|---|---|---|---|---|---|---|---|---|
| | | | nealing | Relative | Leakage | down | mo- | |
| | | | tem- | dielectric | current | voltage | bility μ | Off- |
| | | Composition | perature | constant | (A) | (V) | (cm²/Vs) | current |
| Example | 101 | Composition A | 300° C. | 13.1 | 8.0 × 10⁻⁶ | 2.0 | 33 | <1.0 × 10⁻¹⁰ |
| | 102 | Composition B | 300° C. | 8.9 | 3.0 × 10⁻⁶ | 2.3 | 25 | 1.0 × 10⁻⁹ |
| | 103 | Composition C | 500° C. | 12.3 | 1.0 × 10⁻⁶ | 2.3 | 29 | 1.0 × 10⁻¹⁰ |
| | 104 | Composition B | 300° C. | 8.9 | 2.0 × 10⁻⁶ | 2.3 | 104 | 1.0 × 10⁻⁹ |
| | 105 | Composition B | 180° C. | 9.1 | 2.0 × 10⁻⁶ | 2.2 | 122 | 1.0 × 10⁻⁵ |
| | 106 | Composition D | 300° C. | 6.0 | 1.0 × 10⁻⁶ | 2.5 | 16 | <1.0 × 10⁻¹⁰ |
| | 107 | Composition E | 300° C. | 5.7 | 8.0 × 10⁻⁷ | 2.3 | 14 | 1.0 × 10⁻¹⁰ |
| | 108 | Composition F | 300° C. | 6.2 | 1.0 × 10⁻⁶ | 2.4 | 16 | 1.0 × 10⁻¹⁰ |
| Com- | 101 | Comparative | 300° C. | 3.0 | 1.0 × 10⁻⁸ | 4.0 | 12 | <1.0 × 10⁻¹⁰ |
| parative | | Composition A | | | | | | |
| Example | 102 | — | — | 3.9 | <1.0 × 10⁻⁹ | — | 11 | <1.0 × 10⁻¹⁰ |
| | 103 | Comparative | 300° C. | 8.4 | 1.0 × 10⁻³ | 1.6 | — | — |
| | | Composition B | | | | | | |
| | 104 | Comparative | 300° C. | 4.1 | 2.0 × 10⁻⁸ | 3.5 | — | — |
| | | Composition C | | | | | | |
| | 105 | Comparative | 300° C. | 3.7 | 2.0 × 10⁻⁸ | 3.3 | — | — |
| | | Composition D | | | | | | |

### Measurement of Relative Dielectric Constant

The relative dielectric constant was measured using the mercury probe equipment (MCV-530) manufactured by Semilab.

### Measurement Leakage Current

The leakage current at 2 MV was measured using the mercury probe equipment (MCV-530), manufactured by Semilab.

### Measurement of Carrier Mobility

Using the semiconductor parameter analyzer Agilent 4156C, the change of drain current with respect to gate voltage from −5V to 5V was measured with drain voltage of 0.1 V and TFT size of channel width 90 μm and channel length 10 μm, and calculation of the carrier mobility (unit: cm²/V·sec) was conducted.

### Measurement of Dielectric Breakdown Voltage

Using the mercury probe equipment (MCV-530), manufactured by Semilab, and increasing the voltage at 0.1 V intervals, the voltage at which the current value increased 100 times was recorded.

### Off-Current

Using the semiconductor parameter analyzer Agilent 4156C, the drain current at gate voltage of −2V was measured with drain voltage of 0.1 V and TFT size of channel width 90 μm and channel length 10 μm.

Further, after forming an insulating film in the same manner as in Example 102, an insulating film was similarly formed further using Comparative Composition A, and the other operations were performed in the same manner as in Example 102, thereby forming a thin film transistor in which the insulating films had a two-layer constitution. This thin film transistor had carrier mobility of 22 and off-current of 1.0×10⁻¹⁰.

Reference Compositions B′ and D′ were prepared in the same manner as Composition B or D, except that polyoxyethylene alkyl phosphate used as a dispersant was further contained in an amount of 10 mass % based on the total mass of the composition, and by using them, thin film transistors of Examples 201 and 202 were prepared in the same manner as in Example 101. The relative dielectric constants of Examples 201 and 202 were respectively 10.55 and 6.69, the leakage currents thereof were respectively 2.0×10⁻⁴ and 1.0×10⁻⁵, and the dielectric breakdown voltages thereof were respectively 1.7 and 2.0. Further, the carrier mobility of Example 201 was 4.0 and the off-current thereof was 1.0×10⁻⁷.

### EXPLANATION OF SYMBOLS

1 transistor substrate
2 gate electrode
3 gate insulation film
4 oxide semiconductor layer
5 source electrode
6 drain electrode
7 protective film
8 pixel electrode
9 contact hole

1.-14. (canceled)

15. A gate insulating film forming composition comprising:
(I) a polysiloxane,
(II) barium titanate, and
(III) a solvent,
wherein the content of the barium titanate (II) is 30 to 80 mass % based on the total mass of the polysiloxane (I) and the barium titanate (II).

16. The composition according to claim 15, wherein the polysiloxane comprises a repeating unit represented by the following formula (Ia): 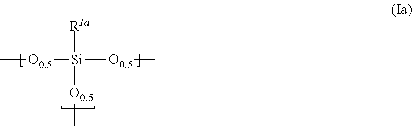
wherein,
R^{Ia} represents hydrogen, a C₁₋₃₀, linear, branched or cyclic, saturated or unsaturated, aliphatic hydrocarbon group or aromatic hydrocarbon group;
the aliphatic hydrocarbon group and the aromatic hydrocarbon group are each unsubstituted or substituted with fluorine, hydroxy or alkoxy, and
in the aliphatic hydrocarbon group and the aromatic hydrocarbon group, methylene is not replaced, or one or more methylene is replaced with oxy, imino or carbonyl, provided that R^{Ia} is not hydroxy or alkoxy.

17. The composition according to claim 15, wherein the polysiloxane further comprises a repeating unit represented by the formula (Ic):

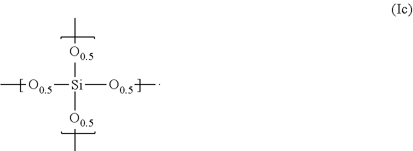

18. The composition according to claim 15, wherein the barium titanate has an average primary particle size of 10 to 200 nm.

19. The composition according to claim 15, wherein the content of the barium titanate (II) is 40 to 80 mass % based on the total mass of the polysiloxane (I) and the barium titanate (II).

20. The composition according to claim 15, wherein the composition further comprises a silanol condensation catalyst.

21. The composition according to claim 15, wherein the composition further comprises a diazonaphthoquinone derivative.

22. The composition according to claim 15, wherein the content of a dispersant is 40 mass % or less based on the total mass of the barium titanate (II).

23. A gate insulating film forming composition consisting of:
(I) a polysiloxane,
(II) barium titanate,
(III) a solvent, and
(IV) an additive selected from the group consisting of a diazonaphthoquinone derivative, a silanol condensation catalyst, a silicon-containing compound and a fluorine-containing compound, in an amount of 0 to 20 mass % based on the total mass of the polysiloxane (I) and the barium titanate (II),
wherein the content of the barium titanate (II) is 30 to 80 mass % based on the total mass of the polysiloxane (I) and the barium titanate (II).

24. A method for manufacturing a gate insulating film comprising:
applying the composition according to claim 15 onto a substrate to form a coating film, and heating the formed coating film.

25. The method according to claim 24, wherein the heating of the coating film is performed at 250 to 800° C.

26. The gate insulating film manufactured by the method according to claim 24, having a relative dielectric constant of 6.0 or more.

27. A thin film transistor comprising:
a gate electrode,
a gate insulating film manufactured by the method according to claim 24,
an oxide semiconductor layer,
a source electrode, and
a drain electrode.

28. The thin film transistor according to claim 27, wherein the thin film transistor further comprises a protective film.
